(19) United States
(12) Patent Application Publication
(10) Pub. No.: US 2025/0116923 A1
(43) Pub. Date: Apr. 10, 2025

(54) RESIST COMPOSITION FOR PHOTOLITHOGRAPHY AND METHOD FOR MANUFACTURING SEMICONDUCTOR DEVICES USING THE SAME

(71) Applicant: Inha University Research and Business Foundation, Incheon (KR)

(72) Inventors: Jinkyun LEE, Incheon (KR); Gyuyeong LEE, Ansan-si (KR); Minkyu CHOI, Uiwang-si (KR); Yejin KU, Incheon (KR)

(73) Assignee: Inha University Research and Business Foundation, Incheon (KR)

(21) Appl. No.: 18/885,962

(22) Filed: Sep. 16, 2024

(30) Foreign Application Priority Data
Sep. 21, 2023 (KR) 10-2023-0126592
Jun. 3, 2024 (KR) 10-2024-0072595

(51) Int. Cl. G03F 7/004; G03F 7/00; G03F 7/20; H01L 21/027

(52) U.S. Cl. CPC G03F 7/0042; G03F 7/0048; G03F 7/2004; G03F 7/70033; H01L 21/0274

(57) ABSTRACT

Provided are a resist composition for photolithography and a method for manufacturing a semiconductor device using the same. The resist composition includes a metal phthalocyanine compound in which an aromatic functional group is introduced. The aromatic functional group has a substituent selected among a vinyl group, a halogenated alkyl group of 1 to 20 carbon atoms, a halogenated alkyl ether halogenated alkyl group of 2 to 20 carbon atoms, a halogenated alkyl ether halogenated alkylene ether halogenated alkyl group of 3 to 20 carbon atoms, and a halogenated aryl group of 6 to 20 carbon atoms.

### CROSS-REFERENCE TO RELATED APPLICATIONS

This U.S. non-provisional patent application claims priority under 35 U.S.C. § 119 of Korean Patent Application Nos. 10-2023-0126592, filed on Sep. 21, 2023, and 10-2024-0072595, filed on Jun. 3, 2024, the entire contents of which are hereby incorporated by reference.

### BACKGROUND

The present disclosure herein relates to a resist composition for photolithography used for manufacturing of a semiconductor device and a method for manufacturing a semiconductor device using the same.

This study was conducted with the support of Samsung Science & Technology Foundation (project number: SRFC-TA1703-51, SRFC-TA1703-05).

Photolithography may include an exposing process and a developing process. The conductance of the exposing process may include exposing a resist layer to a specific wavelength of light to induce the change of the chemical structure of the resist layer. The conductance of the developing process may include the selective removing of the exposed part or the unexposed part of the resist layer by using a solubility difference between the exposed part and the unexposed part.

Recently, as semiconductor devices are highly integrated and downsized, the line width of patterns in semiconductor devices is miniaturized. In order to form minute patterns, various studies are conducted to improve the resolution and sensitivity of resist patterns formed by photolithography and to restrain the collapse of resist patterns. Further, demand for resist patterns with excellent etching resistance to an etching process is also increasing.

### SUMMARY

The present disclosure provides a resist composition with improved dissolution stability and coatability.

The present disclosure also provides a resist composition which may improve the resolution and sensitivity of a photoresist pattern and improve etching resistance of the photoresist pattern.

The present disclosure provides a method for manufacturing a semiconductor device using the resist composition.

The present disclosure is not limited to the aforementioned tasks, and unreferred other tasks may be clearly understood by a person skilled in the art from the description below

A resist composition for photolithography according to the present disclosure may include a metal phthalocyanine compound represented by Formula 1.

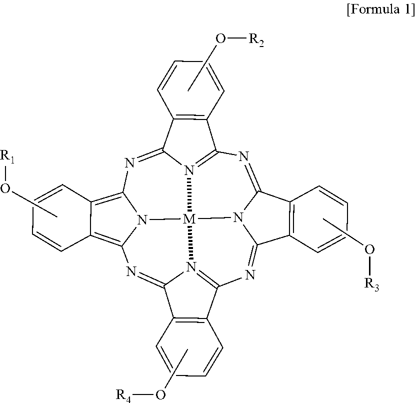

In Formula 1, M is at least one metal selected from tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr) and manganese (Mn), and R₁, R₂, R₃ and R₄ are each independently a functional group represented by Formula 2.

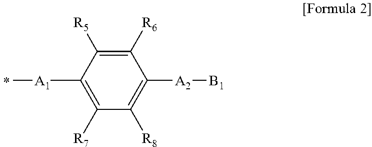

In Formula 2, A₁ and A₂ are each independently a single bond, or a connecting group represented by —CₙH₂ₙ— (“n” is an integer of 1 to 4), —O—, or —CₙH₂ₙ—O— (“n” is an integer of 1 to 4), R₅, R₆, R₇ and R₈ are each independently hydrogen or halogen, B₁ is a vinyl group, a halogenated alkyl group of 1 to 20 carbon atoms, a halogenated alkyl ether halogenated alkyl group of 2 to 20 carbon atoms, a halogenated alkyl ether halogenated alkylene ether halogenated alkyl group of 3 to 20 carbon atoms, or a halogenated aryl group of 6 to 20 carbon atoms, and * is a part bonded to oxygen in Formula 1.

A method for manufacturing a semiconductor device according to the present disclosure may include forming an etching target layer on a substrate, forming a photoresist layer on the etching target layer, and performing an exposing process on the photoresist layer. The exposing process may be performed using extreme ultraviolet or e-beam. The photoresist layer may include a metal phthalocyanine compound in which a fluorinated aromatic functional group is introduced. The fluorinated aromatic functional group may have a substituent selected among a vinyl group, a fluoroalkyl group of 1 to 20 carbon atoms, a fluoroalkyl ether fluoroalkyl group of 2 to 20 carbon atoms, a fluoroalkyl ether fluoroalkylene ether fluoroalkyl group of 3 to 20 carbon atoms, and a fluoroaryl group of 6 to 20 carbon atoms.

A method for manufacturing a semiconductor device according to the present disclosure may include forming an etching target layer on a substrate, and forming a photoresist layer on the etching target layer. The photoresist layer may include a metal phthalocyanine compound represented by Formula 1. In Formula 1, M may be tin (Sn) or zinc (Zn), and R₁, R₂, R₃ and R₄ may be each independently a fluorinated aromatic functional group represented by Formula 2-1, Formula 2-2 or Formula 2-3.

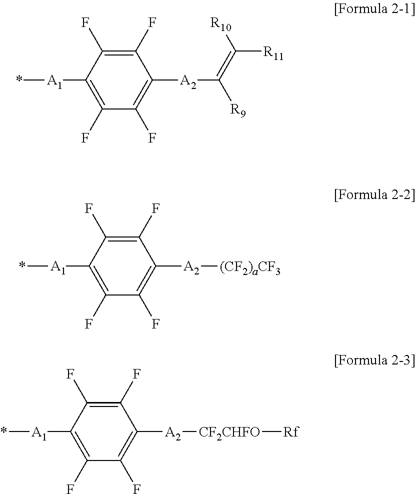

In Formula 2-1, R₉, R₁₀ and R₁₁ are each independently hydrogen, deuterium or an alkyl group of 1 to 3 carbon atoms. In Formula 2-2, “a” is an integer of 0 to 19. In Formula 2-3, Rf has a structure of —CₓF₂ₓ₊₁ or —CₓF₂ₓ—O—C_{y}F_{2y+1}, “x” and “y” are each an integer of 1 or more, and x+y is an integer of 2 to 10. In Formula 2-1 to Formula 2-3, A₁ and A₂ are each independently a single bond, or a connecting group represented by —CₙH₂ₙ—(“n” is an integer of 1 to 4), —O—, or —CₙH₂ₙ—O—(“n” is an integer of 1 to 4), and * is a part bonded to oxygen in Formula 1.

### BRIEF DESCRIPTION OF THE FIGURES

The accompanying drawings are included to provide a further understanding of the inventive concept, and are incorporated in and constitute a part of this specification. The drawings illustrate example embodiments of the inventive concept and, together with the description, serve to explain principles of the inventive concept. In the drawings:

FIG. 1 illustrates optical microscope images of a ZnPc-PFT resist thin film formed according to Example 9;

FIG. 2 is a diagram showing evaluation results on the dissolution stability of resist solutions prepared according to Example 10;

FIG. 3 illustrates optical microscope images of resist thin films after a developing process of e-beam lithography according to Example 11 to Example 13;

FIG. 4 illustrates scanning electron microscope images of negative tone resist patterns formed by an e-beam lithography process according to Example 11 to Example 13;

FIG. 5 illustrates optical microscope images of negative tone resist patterns formed by an extreme ultraviolet lithography process according to Example 14 and Example 15;

FIG. 6 is a graph showing evaluation results on the solubility of resist thin films with respect to an extreme ultraviolet lithography process according to Example 14 and Example 15;

FIG. 7 illustrates scanning electron microscope images of a negative tone resist pattern formed by an extreme ultraviolet lithography process according to Example 16; and

FIG. 8 to FIG. 12 are cross-sectional views showing a method for manufacturing a semiconductor device using the resist composition according to embodiments of the inventive concept.

### DETAILED DESCRIPTION

Preferred embodiments of the inventive concept will be explained with reference to the accompany drawings for sufficient understanding of the configurations and effects of the inventive concept. The inventive concept may, however, be embodied in various forms, have various modifications and should not be construed as limited to the embodiments set forth herein. The embodiments are provided to complete the disclosure of the inventive concept through the explanation of the embodiments and to completely inform a person having ordinary knowledge in this technical field to which the inventive concept belongs of the scope of the inventive concept.

The terminology used herein is for the purpose of describing example embodiments only and is not intended to be limiting of the inventive concept. In the description, the singular forms are intended to include the plural forms as well, unless the context clearly indicates otherwise. It will be further understood that the terms “comprises” and/or “comprising,” when used in this specification, specify the presence of a stated material, constituent element, step, operation and/or device, but do not preclude the presence or addition of one or more other materials, constituent elements, steps, operations and/or devices.

In the description, an alkyl group includes a linear, branched or cyclic monovalent saturated hydrocarbon group, unless otherwise indicated.

In the description, an alkylene group includes a linear, branched or cyclic divalent saturated hydrocarbon group, unless otherwise indicated.

In the description, halogenated alkyl is an alkyl group in which at least one hydrogen is substituted with halogen, halogenated alkylene is an alkylene group in which at least one hydrogen is substituted with halogen, halogenated aryl is an aryl group in which at least one hydrogen is substituted with halogen, and halogenated alkoxy is an alkoxy group in which at least one hydrogen is substituted with halogen.

In the description, fluoroalkyl is an alkyl group in which at least one hydrogen is substituted with fluorine, fluoroalkylene is an alkylene group in which at least one hydrogen is substituted with fluorine, fluoroaryl is an aryl group in which at least one hydrogen is substituted with fluorine, and fluoroalkoxy is an alkoxy group in which at least one hydrogen is substituted with fluorine.

In the description, the term “having a substituent” for a hydrocarbon group means that at least some of the hydrogen atoms of the hydrocarbon group are substituted with functional groups or atoms other than hydrogen atoms. For example, the substituent may be at least one selected from the group consisting of halogen, a hydroxyl group, an alkoxy group, an ether group, a halogenated alkyl group, a halogenated alkoxy group, a halogenated ether group, an alkyl group, an alkenyl group, an aryl group, a hydrocarbon cyclic group and a heterocyclic group.

In the description, a case of not drawing a chemical bond at a position where a chemical bond is necessary, it may mean that a hydrogen atom is bonded, unless otherwise defined.

Hereinafter, embodiments of the inventive concept will be explained in detail with reference to attached drawings.

A resist composition according to embodiments of the inventive concept will be explained.

The resist composition according to embodiments of the inventive concept may be used for the manufacture of a semiconductor device and may be used in a photolithography process for manufacturing the semiconductor device. The resist composition may be used in, for example, an extreme ultraviolet or e-beam lithography process. The extreme ultraviolet may mean ultraviolet having a wavelength of about 10 nm to about 124 nm, in detail, a wavelength of about 13.0 nm to about 13.9 nm, in more detail, a wavelength of about 13.4 nm to about 13.6 nm.

The resist composition may include a metal phthalocyanine compound represented by Formula 1.

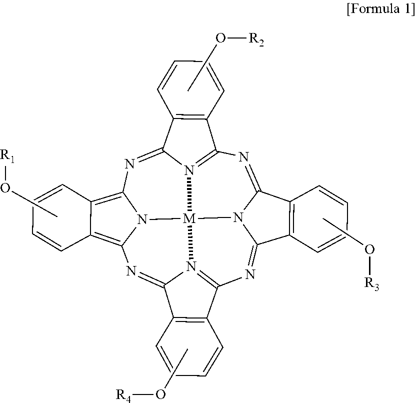

In Formula 1, M is a metal selected from tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr) and manganese (Mn), and R₁, R₂, R₃ and R₄ are each independently a functional group represented by Formula 2.

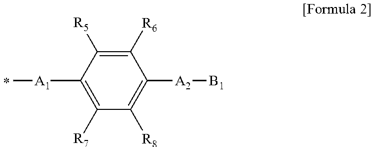

In Formula 2, A₁ and A₂ are each independently a single bond, or a connecting group represented by —CₙH₂ₙ—(“n” is an integer of 1 to 4), —O—, or —CₙH₂ₙ—O—(“n” is an integer of 1 to 4), R₅, R₆, R₇ and R₈ are each independently hydrogen or halogen, B₁ is a vinyl group, a halogenated alkyl group of 1 to 20 carbon atoms, a halogenated alkyl ether halogenated alkyl group of 2 to 20 carbon atoms, a halogenated alkyl ether halogenated alkylene ether halogenated alkyl group of 3 to 20 carbon atoms, or a halogenated aryl group of 6 to 20 carbon atoms.

In Formula 2, * is a part bonded to oxygen in Formula 1.

In some embodiments, in Formula 2, R₅, R₆, R₇ and R₈ may be fluorine, and B₁ may be a vinyl group, a fluoroalkyl group of 1 to 20 carbon atoms, a fluoroalkyl ether fluoroalkyl group of 2 to 20 carbon atoms, a fluoroalkyl ether fluoroalkylene ether fluoroalkyl group of 3 to 20 carbon atoms, or a fluoroaryl group of 6 to 20 carbon atoms.

In an embodiment, in Formula 2, B₁ may be a substituent represented by Formula 3-1, Formula 3-2 or Formula 3-3.

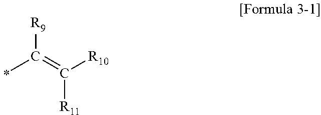

In Formula 3-1, R₉, R₁₀ and R₁₁ are each independently hydrogen, deuterium or an alkyl group of 1 to 3 carbon atoms.

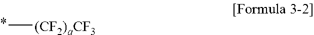

In Formula 3-2, “a” is an integer of 0 to 19.

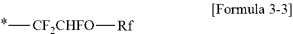

In Formula 3-3, Rf has a structure of —CₓF₂ₓ₊₁ or —CₓF₂ₓ—O—C_{y}F_{2y+1}, “x” and “y” are each an integer of 1 or more, and x+y is an integer of 2 to 10.

In Formula 3-1 to Formula 3-3, * is a part bonded to A₂ in Formula 2.

The substituent represented by Formula 3-3 may include, for example, a substituent represented by Formula 3-3A, Formula 3-3B or Formula 3-3C.

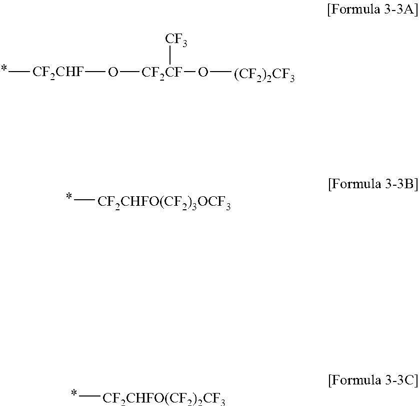

In Formula 3-3A to Formula 3-3C, * is a part bonded to A₂ in Formula 2.

In Formula 1, R₁, R₂, R₃ and R₄ may be each independently an aromatic functional group having a substituent (B₁), which is represented by Formula 2. At least two among R₁, R₂, R₃ and R₄ may be aromatic functional groups having different substituents (B₁). In an embodiment, in Formula 2, R₅, R₆, R₇ and R₈ may be fluorine, and R₁, R₂, R₃ and R₄ may be each independently a fluorinated aromatic functional group having a substituent (B₁), which is represented by Formula 2. At least two among R₁, R₂, R₃ and R₄ may be fluorinated aromatic functional groups having different substituents (B₁).

In some embodiment, in Formula 1, R₁, R₂, R₃ and R₄ may be each independently a fluorinated aromatic functional group represented by Formula 2-1, Formula 2-2 or Formula 2-3.

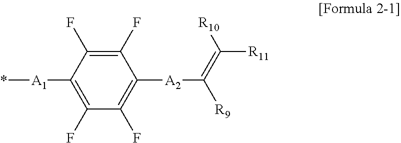

In Formula 2-1, R₉, R₁₀ and R₁₁ are each independently hydrogen, deuterium or an alkyl group of 1 to 3 carbon atoms.

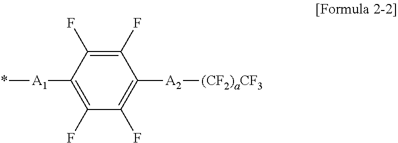

In Formula 2-2, “a” is an integer of 0 to 19.

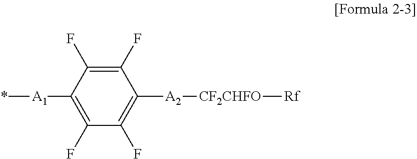

In Formula 2-3, Rf has a structure of —CₓF₂ₓ₊₁ or —CₓF₂ₓ—O—C_{y}F_{2y+1}, “x” and “y” are each an integer of 1 or more, and x+y is an integer of 2 to 10.

In Formula 2-1 to Formula 2-3, A₁ and A₂ are each independently a single bond, or a connecting group represented by —CₙH₂ₙ—(“n” is an integer of 1 to 4), —O—, or —CₙH₂ₙ—O—(“n” is an integer of 1 to 4), and * is a part bonded to oxygen in Formula 1.

In Formula 1, at least two among R₁, R₂, R₃ and R₄ may be fluorinated aromatic functional groups having different structures among Formula 2-1 to Formula 2-3. In an embodiment, at least one among R₁, R₂, R₃ and R₄ may be represented by Formula 2-1, and at least another one among R₁, R₂, R₃ and R₄ may be represented by Formula 2-2 or Formula 2-3. In another embodiment, at least one among R₁, R₂, R₃ and R₄ may be represented by Formula 2-2, and at least another one among R₁, R₂, R₃ and R₄ may be represented by Formula 2-1 or Formula 2-3. In another embodiment, at least one among R₁, R₂, R₃ and R₄ may be represented by Formula 2-3, and at least another one among R₁, R₂, R₃ and R₄ may be represented by Formula 2-1 or Formula 2-2.

The functional group represented by Formula 2-1 may include a functional group represented by Formula 2-1A, and the functional group represented by Formula 2-2 may include a functional group represented by Formula 2-2A. The functional group represented by Formula 2-3 may include a functional group represented by Formula 2-3A.

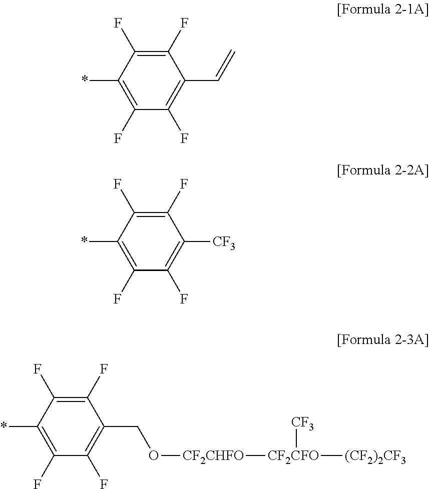

In Formula 2-1A to Formula 2-3A, * is a part bonded to oxygen in Formula 1.

According to some embodiments, the metal phthalocyanine compound represented by Formula 1 may be a zinc phthalocyanine compound represented by Formula 1-1.

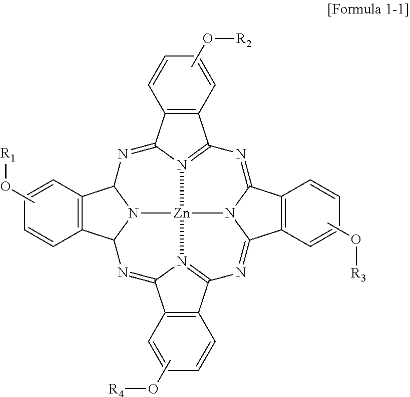

In Formula 1-1, R₁, R₂, R₃ and R₄ are each independently a fluorinated aromatic functional group represented by Formula 2-1, Formula 2-2 or Formula 2-3, and at least two among R₁, R₂, R₃ and R₄ are fluorinated aromatic functional groups having different structures among Formula 2-1 to Formula 2-3.

The resist composition may further include a solvent. The solvent may include an organic solvent or a fluorine-containing solvent. The organic solvent may include at least one among ethers, alcohols, glycol ethers, aromatic hydrocarbon compounds, ketones and esters. For example, the organic solvent may include n-butyl acetate, methyl isobutyl ketone (MIBK), ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (methyl isobutyl carbion: MIBC), hexanol, 1-ethoxy-2-propanol, ethylene glycol, propylene glycol, heptanone, propylene carbonate, butylene carbonate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl 2-hydroxyisobutyrate, methoxybenzene, methoxyethoxy propionate, ethoxyethoxy propionate, or a combination thereof. The fluorine-containing solvent may include, for example, 1,3-bis(trifluoromethyl)benzene (BTMB), benzotrifluoride, 1,1,1,2,3,3-hexafluoro-4-(1,1,2,3,3,3-hexafluoropropoxy) pentane (Novec 7600), 3-ethoxy-1,1,1,2,3,4,4,5,5,6,6,6-dodecafluoro-2-(trifluoromethyl)-hexane (Novec 7500), or a combination thereof.

According to embodiments of the inventive concept, the resist composition may include the metal phthalocyanine compound represented by Formula 1 and the solvent. Aromatic functional groups (for example, fluorinated aromatic functional groups) having different substituents (B₁), represented by Formula 2 may be introduced into the metal phthalocyanine compound. Since the aromatic functional groups (for example, fluorinated aromatic functional groups) having different substituents (B₁) are introduced into the benzene skeleton of the metal phthalocyanine compound, agglomeration between the metal phthalocyanine compounds may be suppressed, and as a result, the solubility of the metal phthalocyanine compound in the solvent may increase. Accordingly, the dissolution stability and coatability of the resist composition may be improved.

Further, the aromatic functional group (for example, fluorinated aromatic functional group) represented by Formula 2 may form radicals by the irradiation of extreme ultraviolet or e-beam, and accordingly, the metal phthalocyanine compound represented by Formula 1 may be easily crosslinked by the irradiation of extreme ultraviolet or e-beam. Accordingly, a photoresist layer formed by using the photoresist composition may have excellent sensitivity and resolution with respect to an e-beam or extreme ultraviolet lithography process. In addition, due to the metal contained in the metal phthalocyanine compound, etching resistance of the photoresist layer may increase.

Accordingly, a metal phthalocyanine-based non-chemically amplified resist composition, which has high resolution and sensitivity with respect to the e-beam or extreme ultraviolet lithography process, and high etching resistance and improved dissolution stability and coatability may be provided.

### [Example 1] Synthesis of Phthalonitrile with Fluorinated Aromatic Functional Group Having Vinyl Group (PFST) (PN-PFST) (Reaction 1)

To a 250 cm³ round flask, 2,3,4,5,6-pentafluorostyrene (6.1 g, 31.2 mmol), 4-hydroxyphthalonitrile (3.0 g, 20.8 mmol), potassium carbonate (K₂CO₃) (14.4 g, 104.0 mmol) and dimethylformamide (DMF, 60 cm³) were injected to prepare a reaction solution. The reaction solution was stirred at about 90° C. for about 3 hours and then, cooled to room temperature. The reaction product was diluted with Et₂O (diethyl ether, 60 cm³) and washed with water and an aqueous saturated sodium chloride solution to prepare an organic solution. The organic solution was dried over anhydrous MgSO₄. A solution obtained by concentrating under a reduced pressure was purified by a column chromatography method (silica gel, EtOAc (ethyl acetate):hexane=1:3) to obtain PFST-phthalonitrile (PN-PFST) in a solid phase (2.1 g, yield: 32%).

¹H NMR (400 MHZ, acetone-d₆); δ=8.16-8.11 (d, J=8.8 Hz, 1H, Ar—H), 7.95-7.92 (d, J=2.5 Hz, 1H, Ar—H), 7.79-7.73 (dd, J=8.8, 2.6 Hz, 1H, Ar—H), 6.81-6.71 (dd, J=18, 12 Hz, 1H, vinyl CH), 6.18-6.09 (d, J=18 Hz, 1H, vinyl CH₂), 5.88-5.81 (d, J=12 Hz, 1H, vinyl CH₂).

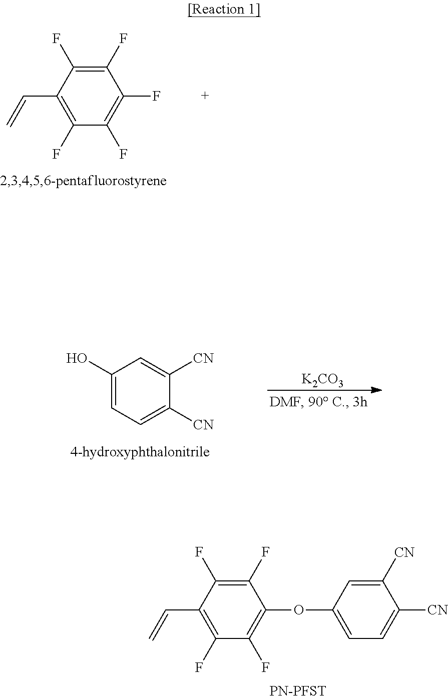

### [Example 2] Synthesis of Phthalonitrile with Fluorinated Aromatic Functional Group Having Fluorinated Alkyl Group (PFT) (PN-PFT) (Reaction 2)

To a 100 cm³ round flask, octafluorotoluene (3.9 g, 16.7 mmol), 4-hydroxyphthalonitrile (2.0 g, 13.9 mmol), K₂CO₃ (2.6 g, 20.8 mmol) and dimethylformamide (DMF, 40 cm³) were injected to prepare a reaction solution. The reaction solution was stirred at about 90° C. for about 3 hours and then, cooled to room temperature. The reaction product was diluted with Et₂O (40 cm³) and washed with water and an aqueous saturated sodium chloride solution to prepare an organic solution. The organic solution was dried over anhydrous MgSO₄. A solution obtained by concentrating under reduced pressure conditions was purified by a column chromatography method (silica gel, EtOAc:hexane=1:3) to obtain PFT-phthalonitrile (PN-PFT) in a solid phase (3.5 g, yield: 70%).

¹H NMR (400 MHZ, acetone-d₆); δ=8.21-8.14 (d, J=8.8 Hz, 1H, Ar—H), 7.99-7.92 (d, J=2.3 Hz, 1H, Ar—H), 7.86-7.80 (dd, J=8.8, 2.5 Hz, 1H, Ar—H).

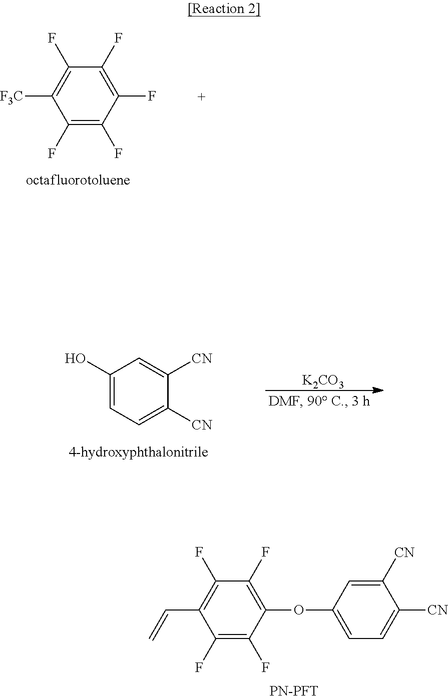

### [Example 3] Synthesis of Fluorinated Aromatic Functional Group with Fluoroalkyl Ether Chain (L-arene) (Reaction 3)

To a 100 cm³ round flask, pentafluorobenzyl alcohol (3.5 g, 17.6 mmol), perfluoro (5-methyl-3,6-dioxanon-1-ene) (7.6 g, 17.6 mmol), KOH (1.5 g, 26.5 mmol) and tetrahydrofuran (THF, 50 cm³) were injected to prepare a reaction solution. The reaction solution was stirred at about 50° C. for about 18 hours and then, cooled to room temperature. The reaction product was diluted with hexane (50 cm³) and washed with water and an aqueous saturated sodium chloride solution to prepare an organic solution. The organic solution was dried over anhydrous MgSO₄. A solution obtained by concentrating under reduced pressure conditions was purified by a column chromatography method (silica gel, EtOAc:hexane=1:8) to obtain L-arene in a solid phase (7.7 g, yield: 69%).

¹H NMR (400 MHZ, CDCl₃); δ=5.95-5.75 (d, J=53.6 Hz, 1H, CF₂CFHO), 5.16-5.07 (s, 2H, Ar—CH₂O).

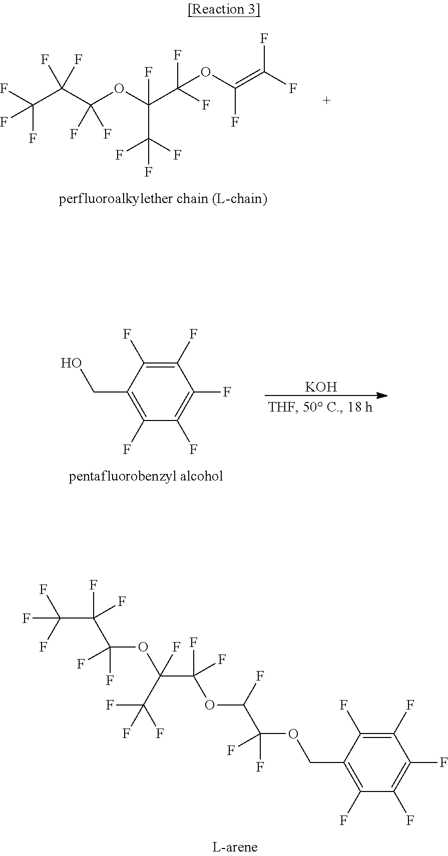 [SMILES: FC(F)=C(F)OC(F)(F)C(F)(OC(F)(F)C(F)(F)C(F)(F)F)C(F)(F)F ; OCc1c(F)c(F)c(F)c(F)c1F ; "KOH" ; Fc1c(F)c(F)c(COC(F)(F)C(F)OC(F)(F)C(F)(OC(F)(F)C(F)(F)C(F)(F)F)C(F)(F)F)c(F)c1F]

### [Example 4] Synthesis of Phthalonitrile with Fluorinated Aromatic Functional Group Having Fluoroalkyl Ether Chain (L-Arene) (PN-L-Arene) (Reaction 4)

To a 500 cm³ round flask, 1,2,3,4,5-pentafluoro-6-((1,1,2-trifluoro-2-(1,1,2,3,3,3-hexafluoro-2-(perfluoropropoxy) propoxy) ethoxy)methyl)benzene (L-arene) (23.4 g, 37.1 mmol), 4-hydroxyphthalonitrile (7.0 g, 48.2 mmol), K₂CO₃ (25.6 g, 185.3 mmol) and dimethylformamide (DMF, 115 cm³) were injected to prepare a reaction solution. The reaction solution was stirred at about 60° C. for about 5 hours and then, cooled to room temperature. The reaction product was diluted with Et₂O (115 cm³) and washed with water and an aqueous saturated sodium chloride solution to prepare an organic solution. The organic solution was dried over anhydrous MgSO₄. A solution obtained by concentrating under reduced pressure conditions was purified by a column chromatography method (silica gel, EtOAc:hexane=1:2) to obtain L-arene-phthalonitrile (PN-L-arene) in a solid phase (3.3 g, yield: 12%).

¹H NMR (400 MHZ, acetone-d₆); δ=8.20-8.10 (s, 1H, Ar—H), 7.97-7.89 (s, 1H, Ar—H), 7.80-7.71 (s, 1H, Ar—H), 6.86-6.64 (d, 1H, J=52.4 Hz, CF₂CFHO), 5.39-5.26 (s, 2H, Ar—CH₂O).

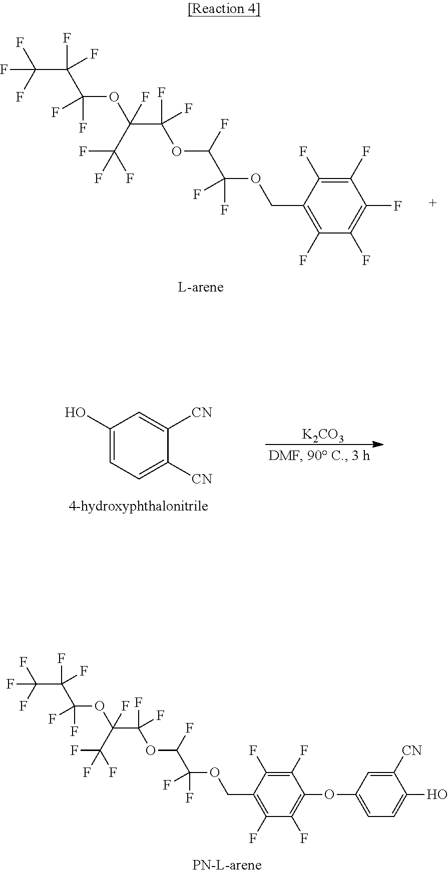 [SMILES: Fc1c(F)c(F)c(COC(F)(F)C(F)OC(F)(F)C(F)(OC(F)(F)C(F)(F)C(F)(F)F)C(F)(F)F)c(F)c1F ; N#Cc1ccc(O)cc1C#N ; "K2CO3" ; N#Cc1cc(Oc2c(F)c(F)c(COC(F)(F)C(F)OC(F)(F)C(F)(OC(F)(F)C(F)(F)C(F)(F)F)C(F)(F)F)c(F)c2F)ccc1O]

### [Example 5] Synthesis of Zinc Phthalocyanine with PFST (ZnPc-PFST) (Reaction 5)

To a 50 cm³ round flask, PN-PFST (0.5 g, 1.57 mmol), Zn(OAc)₂ (0.3 g, 0.39 mmol), hexamethyldisilazane (HMDS, 0.5 g, 3.14 mmol), and N,N-dimethylformamide (DMF, 1 cm³) were injected to prepare a reaction solution. The reaction solution was stirred at about 100° C. for about 24 hours and then, cooled to room temperature to form a reaction product. The reaction product was concentrated under reduced pressure conditions. The solid thus obtained was washed with water and MeOH, and the residual solid was purified by a column chromatography method (silica gel, EtOAc:hexane=1:2) to obtain ZnPc-PFST in a solid phase (0.2 g, yield: 38%).

¹H NMR (400 MHZ, acetone-d₆); δ=8.69-8.15 (m, 8H, Ar—H), 7.91-7.70 (td, 4H, J=19.3, 8.2 Hz, Ar—H), 7.02-6.83 (m, 4H, vinyl CH), 6.38-6.23 (m, 4H, vinyl CH₂), 6.01-5.85 (t, 4H, vinyl CH₂). UV-Vis (THF): λₘₐₓ (nm) (log ε670. IR [(KBr: vₘₐₓ, (cm⁻¹)] 3076-2923 (C—H), 1660 (C═C), 1608 (C—C), 1521-1445 (C—H), 1332 (C—C), 1284 (C—N), 1060 (C—N), 634 (C—C).

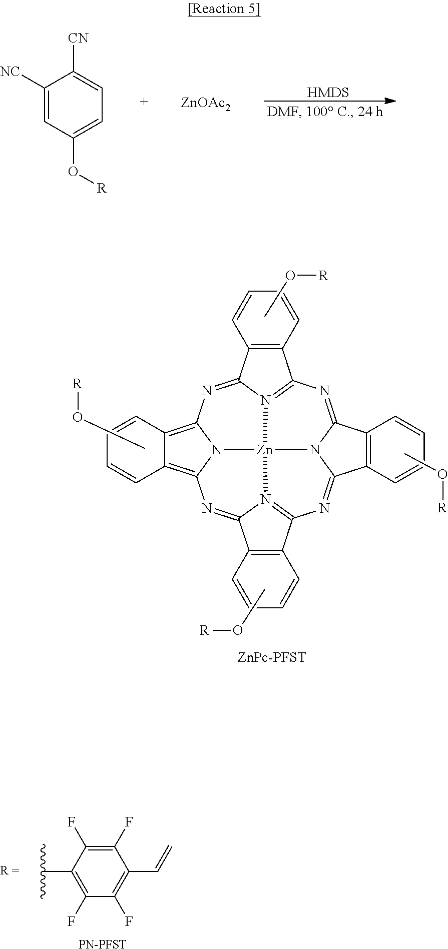

### [Example 6] Synthesis of Zinc Phthalocyanine with PFT (ZnPc-PFT) (Reaction 6)

To a 100 cm³ round flask, PN-PFT (2.0 g, 5.55 mmol), Zn(OAc)₂ (0.3 g, 1.39 mmol), 1,8-diazabicyclo [5,4,0] undec-7-ene (DBU, 0.4 g, 2.72 mmol), and n-pentanol (20 cm³) were injected to prepare a reaction solution. The reaction solution was refluxed at about 140° C. for about 24 hours. The reaction product was cooled to room temperature and concentrated under reduced pressure conditions, and the solid thus obtained was purified by a column chromatography method (silica gel, EtOAc:hexane=1:2) to obtain ZnPc-PFT in a solid phase (0.2 g, yield: 20%).

¹H NMR (400 MHZ, acetone-d₆); δ=8.77-8.37 (ddd, 8H, J=46.3, 37.2, 17.6 Hz, Ar—H), 8.01-7.81 (m, 4H, Ar—H). UV-Vis (THF): λₘₐₓ (nm) (log ε670. IR [(KBr): vₘₐₓ, (cm⁻¹)] 3076-2923 (C—H), 1660 (C═C), 1608 (C—C), 1521-1445 (C—H), 1332 (C—C), 1284 (C—N), 1213 (C—F₃), 1060 (C—N), 634 (C—C).

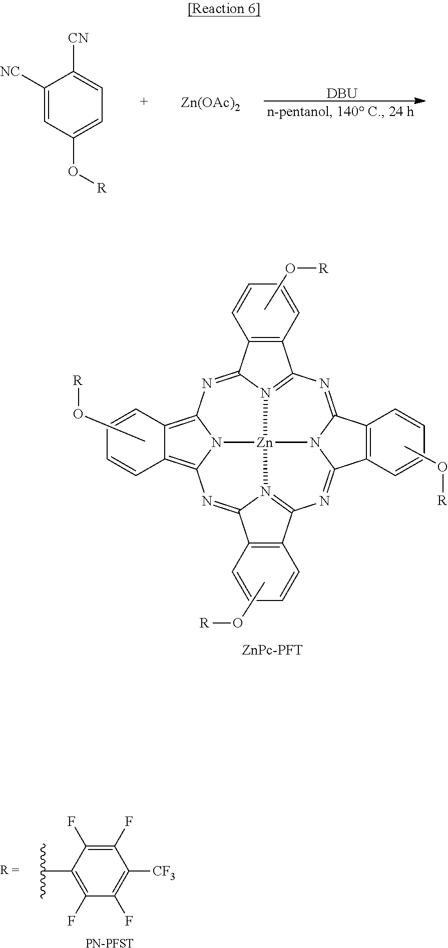

### [Example 7] Synthesis of Zinc Phthalocyanine with Probabilistically Introduced Fluorinated Aromatic Functional Group Having Vinyl group (PFST) and Fluorinated Aromatic Functional Group having Fluoroalkyl Group (PFT) (ZnPc-Ar_{M}) (Reaction 7)

To a 100 cm³ round flask, PN-PFST (0.6 g, 1.89 mmol), PN-PFT (0.7 g, 1.89 mmol), Zn(OAc)₂ (0.2 g, 0.95 mmol), 1,8-diazabicyclo [5,4,0] undec-7-ene (DBU, 0.06 g, 0.10 mmol), and n-pentanol (25 cm³) were injected to prepare a reaction solution. The reaction solution was refluxed at about 140° C. for about 24 hours. The reaction product was cooled to room temperature and then concentrated under reduced pressure conditions, and the solid thus obtained was purified by a column chromatography method (silica gel, EtOAc:hexane=1:2) to obtain ZnPc-Ar_{M} in a solid phase (0.4 g, yield: 32%).

¹H NMR (400 MHZ, acetone-d₆); δ=8.67-8.13 (dd, 8H, J=67.9, 33.2 Hz, Ar—H), 7.95-7.54 (m, 4H, Ar—H), 7.02-6.87 (m, 2H, vinyl CH), 6.37-6.24 (m, 2H, vinyl CH₂), 5.99-5.88 (d, 2H, J=10.3 Hz, vinyl CH₂). UV-Vis (THF): λₘₐₓ (nm) (log ε670. IR [(KBr): vₘₐₓ, (cm⁻¹)] 3076-2923 (C—H), 1660 (C═C), 1608 (C—C), 1521-1445 (C—H), 1332 (C—C), 1284 (C—N), 1213 (C—F₃), 1060 (C—N), 634 (C—C).

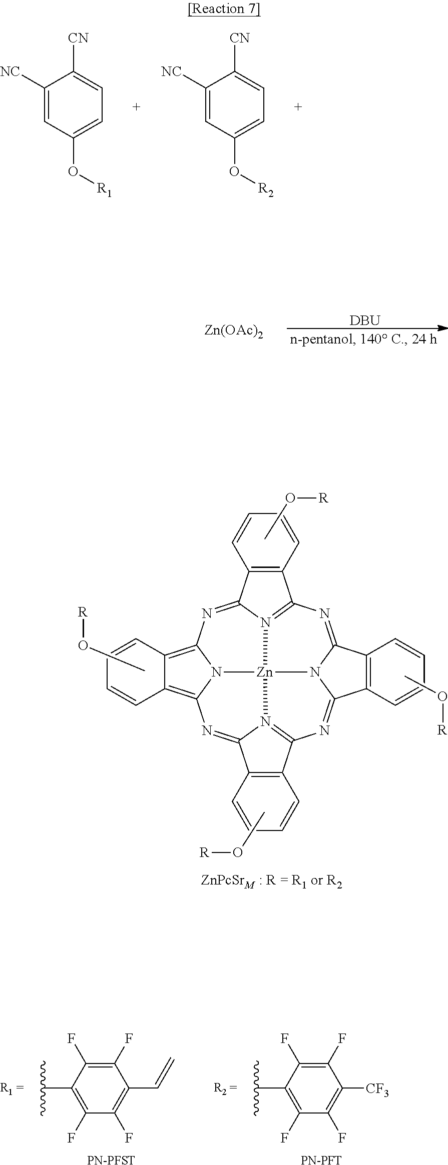

### [Example 8] Synthesis of Zinc Phthalocyanine with Probabilistically Introduced Fluorinated Aromatic Functional Group having Vinyl group (PFST) and Fluorinated Aromatic Functional Group having Fluoroalkyl Ether Chain (L-arene) (ZnPc-LAr_{M}) (Reaction 8)

To a 100 cm³ round flask, PN-PFST (0.2 g, 0.57 mmol), PN-L-arene (0.4 g, 0.57 mmol), Zn(OAc)₂ (0.05 g, 0.28 mmol), 1,8-diazabicyclo [5,4,0] undec-7-ene (DBU, 0.02 g, 0.11 mmol), and n-pentanol (20 cm³) were injected to prepare a reaction solution. The reaction solution was refluxed at about 150° C. for about 24 hours. The reaction product was cooled to room temperature and then concentrated under reduced pressure conditions, and the solid thus obtained was purified by a column chromatography method (silica gel, EtOAc:hexane=1:2) to obtain ZnPc-LAr_{M} in a solid phase (0.23 g, yield: 18%).

¹H NMR (400 MHZ, acetone-d₆); δ=8.75-8.29 (d, 8H, J=28.4 Hz, Ar—H), 7.92-7.73 (s, 4H, Ar—H), 6.98-6.77 (d, 4H, J=50.9 Hz, vinyl CH, CF₂CFHO), 6.36-6.21 (s, 2H, vinyl CH₂), 5.97-5.85 (s, 2H, vinyl CH₂), 5.61-5.43 (s, 4H, Ar—CH₂O). UV-Vis (THF): λₘₐₓ (nm) (log ε670. IR [(KBr): vₘₐₓ, (cm⁻¹)] 1654 (C═C), 1614 (C—C), 1525-1448 (C—H), 1336 (C—C), 1247 (C—N), 1200-1100 (C—F₂), 1052 (C—N), 880 (C—N).

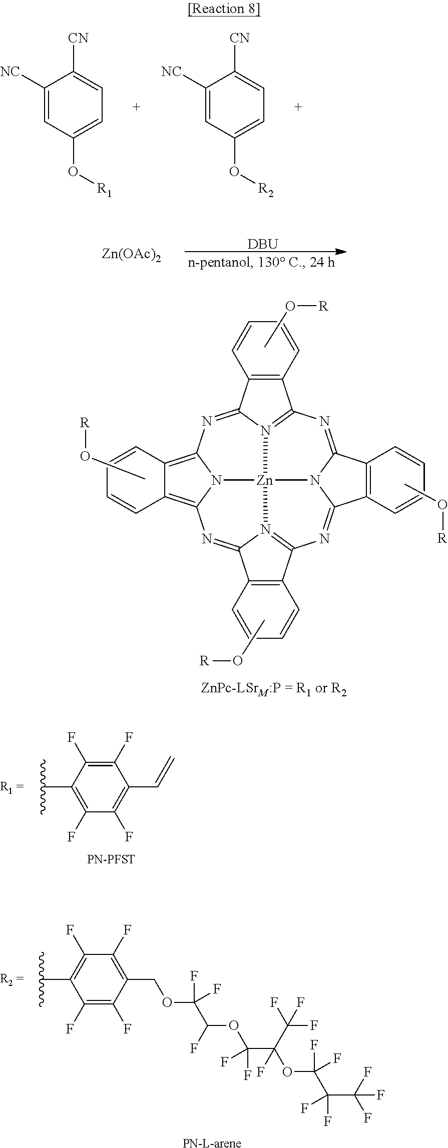

### [Example 9] Coatability Evaluation of Resist Composition

### 1) Coatability Evaluation of Resist Composition Including ZnPc-PFST

In a mixture solvent of n-butyl acetate (nBA) and methyl isobutyl ketone (MIBK) in a ratio of about 1:2, ZnPc-PFST synthesized in Example 5 was dissolved to prepare a solution of about 3 wt/vol %. The solution was applied on a silicon substrate via spin coating at about 3000 rpm for about 60 seconds, and heated at about 80° C. for about 1 minute to form a resist thin film (thickness of about 100 nm).

### 2) Coatability Evaluation of Resist Composition Including ZnPc-PFT

In a mixture solvent of n-butyl acetate (nBA) and methyl isobutyl ketone (MIBK) in a ratio of about 1:2, ZnPc-PFT synthesized in Example 6 was dissolved to prepare a solution of about 3 wt/vol %. The solution was applied on a silicon substrate via spin coating at about 3000 rpm for about 60 seconds, and heated at about 80° C. for about 1 minute to form a resist thin film (thickness of about 100 nm).

### 3) Coatability Evaluation of Resist Composition Including ZnPc-Ar_{M}

In a mixture solvent of n-butyl acetate (nBA) and methyl isobutyl ketone (MIBK) in a ratio of about 1:2, ZnPc-Ar_{M} synthesized in Example 7 was dissolved to prepare a solution of about 3 wt/vol %. The solution was applied on a silicon substrate via spin coating at about 3000 rpm for about 60 seconds, and heated at about 80° C. for about 1 minute to form a resist thin film (thickness of about 100 nm).

### 4) Coatability Evaluation of Resist Composition Including ZnPc-LAr_{M}

In a 1,3-bis(trifluoromethyl)benzene (BTMB) solvent, ZnPc-LAr_{M} synthesized in Example 8 was dissolved to prepare a solution of about 3 wt/vol %. The solution was applied on a silicon substrate via spin coating at about 3000 rpm for about 60 seconds, and heated at about 80° C. for about 1 minute to form a resist thin film (thickness of about 100 nm).

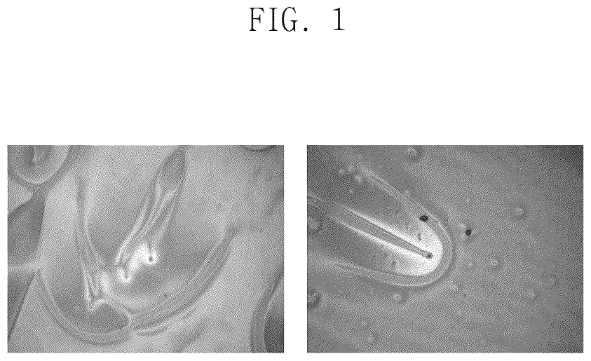

FIG. 1 illustrates optical microscope images on a ZnPc-PFT resist thin film formed according to Example 9.

Referring to FIG. 1, it can be confirmed that in a case of ZnPc-PFT introducing a single type of a fluorinated aromatic functional group, a non-uniform resist thin film was formed due to the agglomeration between metal phthalocyanine compounds. Differently, in cases of ZnPc-PFST introducing a single type of a fluorinated aromatic functional group, and ZnPc-Ar_{M} and ZnPc-LAr_{M} which are introducing different types of fluorinated aromatic functional groups, a uniform resist thin film with a thickness of about 100 nm was formed.

### [Example 10] Dissolution Stability Evaluation of Resist Composition

### 1) Stability Evaluation of Resist Composition Including ZnPc-PFST

In a mixture solvent of n-butyl acetate (nBA) and methyl isobutyl ketone (MIBK) in a ratio of about 1:2, ZnPc-PFST synthesized in Example 5 was dissolved to prepare a solution of about 3 wt/vol %. It was observed whether agglomeration occurred in the solution over time.

### 2) Stability Evaluation of Resist Composition Including ZnPc-Ar_{M}

In a mixture solvent of n-butyl acetate (nBA) and methyl isobutyl ketone (MIBK) in a ratio of about 1:2, ZnPc-Ar_{M} synthesized in Example 7 was dissolved to prepare a solution of about 3 wt/vol %. It was observed whether agglomeration occurred in the solution over time.

### 3) Stability Evaluation of Resist Composition Including ZnPc-LAr_{M}

In a 1,3-bis(trifluoromethyl)benzene (BTMB) solvent, ZnPc-LAr_{M} synthesized in Example 8 was dissolved to prepare a solution of about 3 wt/vol %. It was observed whether agglomeration occurred in the solution over time.

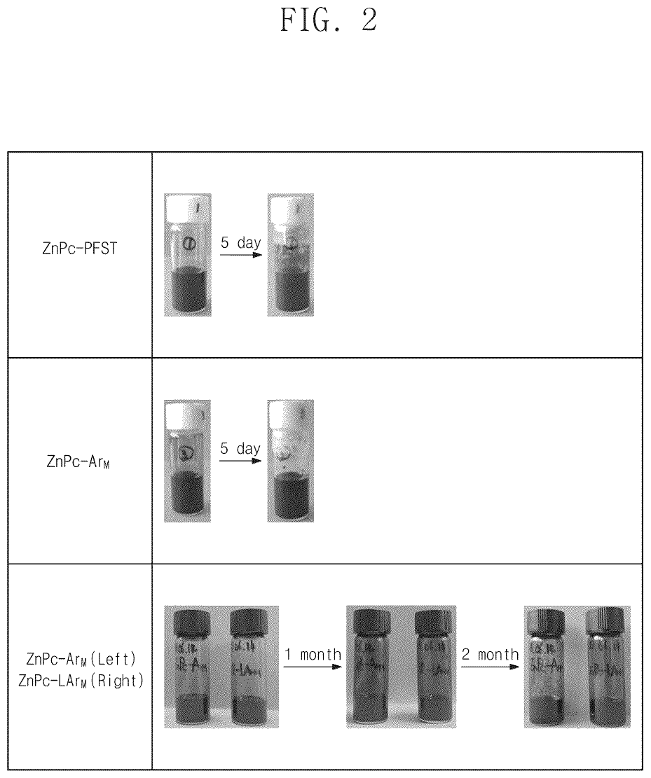

FIG. 2 is a diagram showing evaluation results on the dissolution stability of the resist solutions prepared according to Example 10.

Referring to FIG. 2, it can be confirmed that in a case of ZnPc-PFST introducing a single type of a fluorinated aromatic functional group, agglomeration phenomenon occurred in the solution after 5 days. Differently, in a case of ZnPc-Ar_{M} introducing different types of fluorinated aromatic functional groups, it was confirmed that a stable solution state was maintained even after 5 days. Further, in cases of ZnPc-Ar_{M} and ZnPc-LAr_{M} which are introducing different types of fluorinated aromatic functional groups, it was confirmed that a stable solution state was maintained without agglomeration phenomenon in the solutions even after 2 months.

### [Example 11] E-beam Lithography Evaluation on ZnPc-PFST Thin Film

In a mixture solvent of n-butyl acetate (nBA) and methyl isobutyl ketone (MIBK) in a ratio of about 1:2, ZnPc-PFST synthesized in Example 5 was dissolved to prepare a solution of about 3 wt/vol %. The solution was applied on a silicon substrate via spin coating at about 3000 rpm for about 60 seconds, and heated at about 80° C. for about 1 minute to form a resist thin film (thickness of about 100 nm). On the resist thin film, e-beam with about 500 μC/cm² to about 2000 μC/cm² was irradiated under an accelerated voltage of about 80 keV, and a developing process was conducted using a mixture solution of benzotrifluoride (BTF) and toluene in a ratio of about 2:1 for about 90 seconds to form a negative tone resist pattern with a size of about 100 nm.

### [Example 12] E-beam Lithography Evaluation on ZnPc-Ar_{M} Thin Film

In a mixture solvent of n-butyl acetate (nBA) and methyl isobutyl ketone (MIBK) in a ratio of about 1:2, ZnPc-Ar_{M} synthesized in Example 7 was dissolved to prepare a solution of about 3 wt/vol %. The solution was applied on a silicon substrate via spin coating at about 3000 rpm for about 60 seconds, and heated at about 80° C. for about 1 minute to form a resist thin film (thickness of about 100 nm). On the resist thin film, e-beam with about 500 μC/cm² to about 2000 μC/cm² was irradiated under an accelerated voltage of about 80 keV, and a developing process was conducted using isopropanol (ⁱPrOH) for about 15 seconds to form a negative tone resist pattern with a size of about 70 nm to about 100 nm.

### [Example 13] E-Beam Lithography Evaluation on ZnPc-LAr_{M} Thin Film

In a 1,3-bis(trifluoromethyl)benzene (BTMB) solvent, ZnPc-LAr_{M} synthesized in Example 8 was dissolved to prepare a solution of about 3 wt/vol %. The solution was applied on a silicon substrate via spin coating at about 3000 rpm for about 60 seconds, and heated at about 100° C. for about 1 minute to form a resist thin film (thickness of about 100 nm). On the resist thin film, e-beam with about 500 μC/cm² to about 2000 μC/cm² was irradiated under an accelerated voltage of about 80 keV, and a developing process was conducted using benzotrifluoride (BTF) solution for about 10 seconds to form a negative tone resist pattern with a size of about 90 nm to about 100 nm.

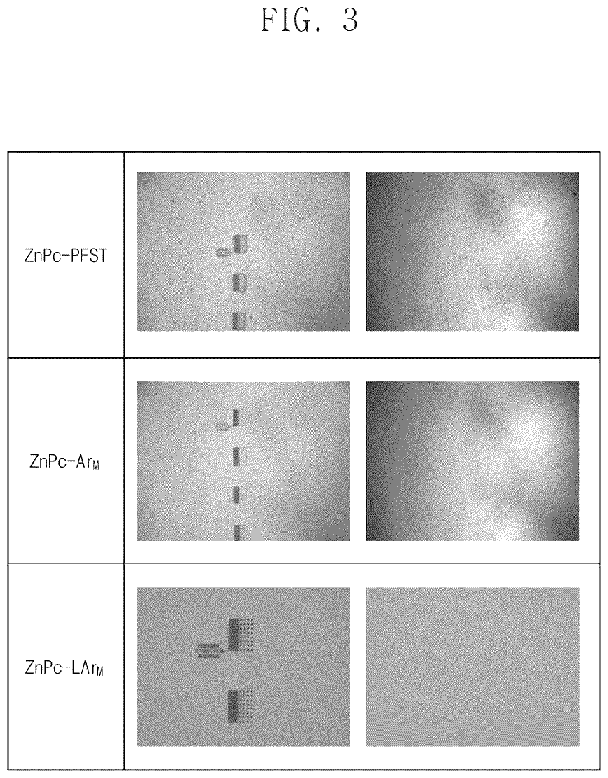

FIG. 3 illustrates optical microscope images on resist thin films after a developing process of an e-beam lithography according to Example 11 to Example 13.

Referring to FIG. 3, in a case of ZnPc-PFST introducing a single type of a fluorinated aromatic functional group, it was confirmed that particle-shaped contaminants remained on the resist thin film after the developing process of the e-beam lithography. Differently, in cases of ZnPc-Ar_{M} and ZnPc-LAr_{M} which are introducing different types of fluorinated aromatic functional groups, it was confirmed that no residual particles (contaminants) remained on the resist thin films after the developing process of the e-beam lithography, and the surfaces of the resist thin films remained clean.

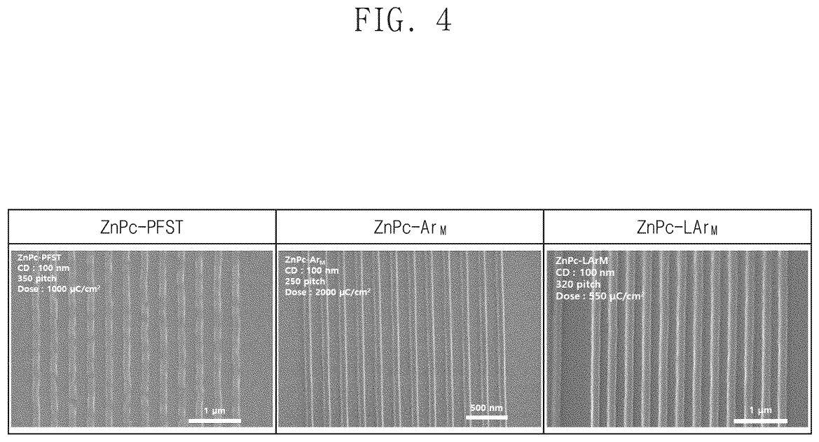

FIG. 4 illustrates scanning electron microscope images on negative tone resist patterns formed by an e-beam lithography process according to Example 11 to Example 13.

Referring to FIG. 4, in a case of ZnPc-PFST introducing a single type of a fluorinated aromatic functional group, it was confirmed that the line edge roughness (LER) of the resist pattern increased. Differently, in cases of ZnPc-Ar_{M} and ZnPc-LAr_{M} which are introducing different types of fluorinated aromatic functional groups, it was confirmed that negative tone resist patterns with a size of about 100 nm, having excellent LER were formed.

### [Example 14] Extreme Ultraviolet Lithography Evaluation on ZnPc-Ar_{M} Thin Film (Solubility Change Evaluation)

In a mixture solvent of n-butyl acetate (nBA) and methyl isobutyl ketone (MIBK) in a ratio of about 1:2, ZnPc-Ar_{M} synthesized in Example 7 was dissolved to prepare a solution of about 3 wt/vol %. The solution was applied on a silicon substrate via spin coating at about 3000 rpm for about 60 seconds, and heated at about 80° C. for about 1 minute to form a resist thin film (thickness of about 100 nm). On the resist thin film, extreme ultraviolet extracted from the Pohang Radiation light Accelerator was irradiated under dosage conditions ranging from about 3 mJ/cm² to about 60 mJ/cm², and a developing process was conducted using isopropanol (ⁱPrOH) for about 12 seconds. As a result, a circular negative tone resist pattern was formed. According to the dosage, the thickness of the resist pattern (that is, the thickness of the resist pattern remaining after the developing process) was measured, and the change in solubility of the resist thin film was evaluated. The thickness of the resist pattern was measured through Alpha-step®D-300 stylus profiler manufactured by Kla-Tencor Co.

### [Example 15] Extreme Ultraviolet Lithography Evaluation on ZnPc-LAr_{M} Thin Film (Solubility Change Evaluation)

In a 1,3-bis(trifluoromethyl)benzene (BTMB) solvent, ZnPc-LAr_{M} synthesized in Example 8 was dissolved to prepare a solution of about 3 wt/vol %. The solution was applied on a silicon substrate via spin coating at about 3000 rpm for about 60 seconds, and heated at about 100° C. for about 1 minute to form a resist thin film (thickness of about 100 nm). On the resist thin film, extreme ultraviolet extracted from the Pohang Radiation light Accelerator was irradiated under dosage conditions ranging from about 3 mJ/cm² to about 60 mJ/cm², and a developing process was conducted using isopropanol (ⁱPrOH) for about 10 seconds. As a result, a circular negative tone resist pattern was formed. According to the dosage, the thickness of the resist pattern (that is, the thickness of the resist pattern remaining after the developing process) was measured, and the change in solubility of the resist thin film was evaluated. The thickness of the resist pattern was measured through Alpha-step®D-300 stylus profiler manufactured by Kla-Tencor Co.

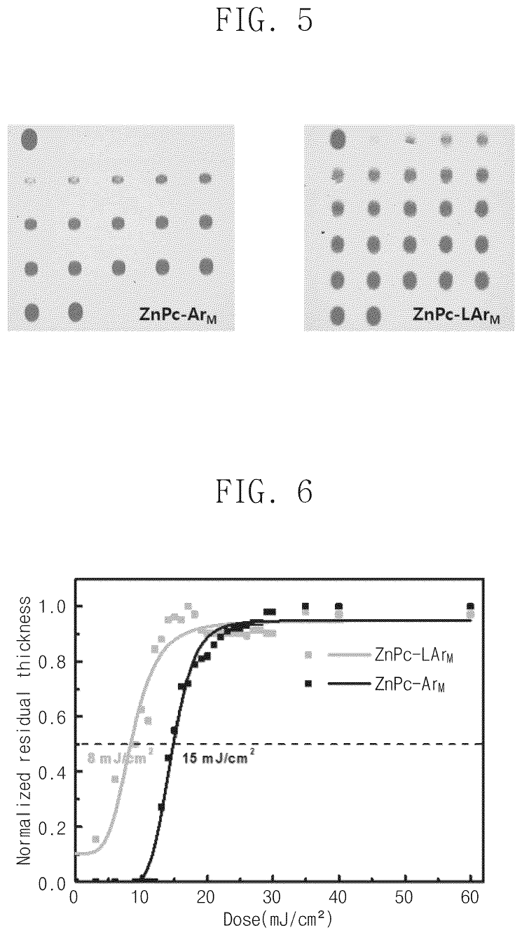

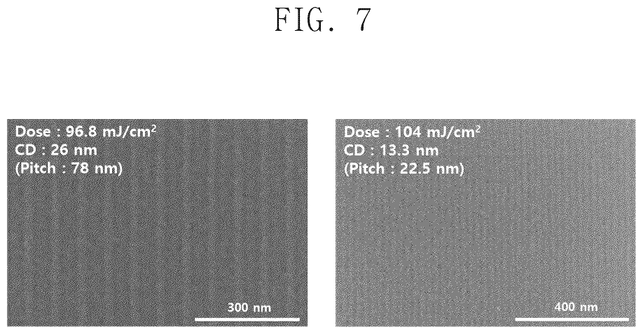

FIG. 5 illustrates optical microscope images on negative tone resist patterns formed by an extreme ultraviolet lithography process according to Example 14 and Example 15, and FIG. 6 is a graph showing the evaluation results on the solubility of resist thin films with respect to an extreme ultraviolet lithography process according to Example 14 and Example 15.

Referring to FIG. 5, in cases of ZnPc-Ar_{M} and ZnPc-LAr_{M} which are introducing different types of fluorinated aromatic functional groups, it was confirmed that negative tone resist patterns with a circular shape were formed by conducting the extreme ultraviolet lithography process on the resist thin films.

Referring to FIG. 6, in a case of ZnPc-Ar_{M}, when extreme ultraviolet of about 15 mJ/cm² was irradiated onto the resist thin film, the thickness of the resist pattern was maintained by about 50% of the thickness of the resist thin film. In a case of ZnPc-LAr_{M}, when extreme ultraviolet of about 8 mJ/cm² was irradiated onto the resist thin film, the thickness of the resist pattern was maintained by about 50% of the thickness of the resist thin film.

### [Example 16] Extreme Ultraviolet Lithography Evaluation on ZnPc-LAr_{M} Thin Film (Resist Pattern Formation)

In a 1,3-bis(trifluoromethyl)benzene (BTMB) solvent, ZnPc-LAr_{M} synthesized in Example 8 was dissolved to prepare a solution of about 0.8 wt/vol %. The solution was applied on a silicon substrate via spin coating at about 5000 rpm for about 60 seconds, and heated at about 100° C. for about 1 minute to form a resist thin film (thickness of about 17 nm). Then, extreme ultraviolet was irradiated under dosage conditions ranging from about 60 mJ/cm² to about 140 mJ/cm², using the MET5 lithography machine owned by Lawrence Berkeley National Laboratory, and a developing process was conducted using benzotrifluoride (BTF) solution for about 10 seconds. As a result, a negative tone resist pattern was formed.

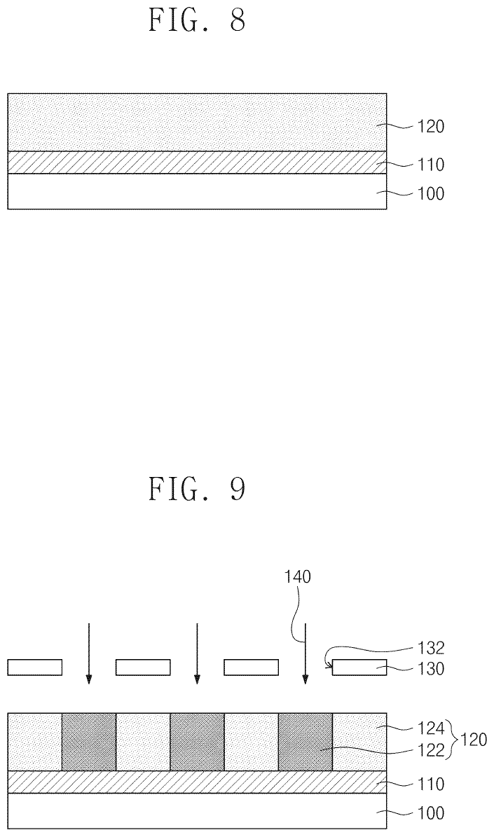

FIG. 7 illustrates scanning electron microscope images on a negative tone resist pattern formed by the extreme ultraviolet lithography process according to Example 16.

Referring to FIG. 7, a resist thin film with a thickness of about 17 nm was formed using ZnPc-LAr_{M} introducing different types of fluorinated aromatic functional groups, and an extreme ultraviolet lithography process was conducted on the resist thin film. As a result, a negative tone resist pattern having line widths of about 13.3 nm and about 26 nm was formed.

A method for manufacturing a semiconductor device using the resist composition according to embodiments of the inventive concept will be explained.

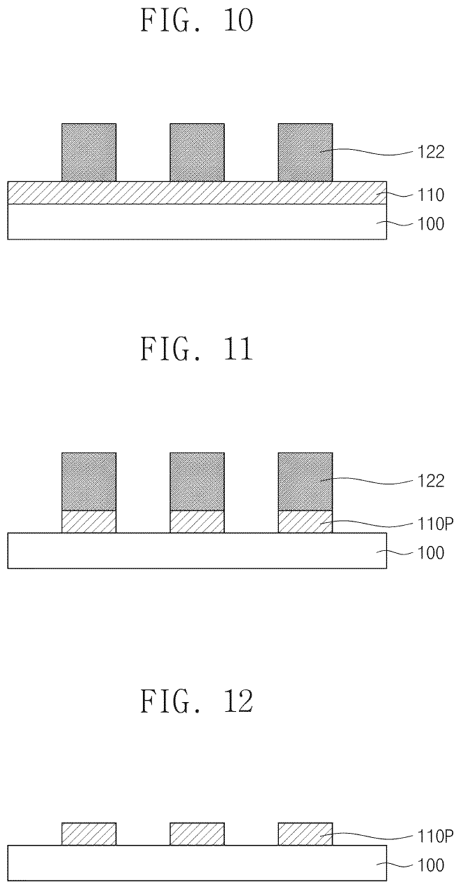

FIG. 8 to FIG. 12 are cross-sectional views showing a method for manufacturing a semiconductor device using the resist composition according to embodiments of the inventive concept.

Referring to FIG. 8, an etching target layer 110 may be formed on a substrate 100, and on the etching target layer 110, a photoresist layer 120 may be formed. The substrate 100 may be a semiconductor substrate, for example, a silicon substrate, a germanium substrate or a silicon/germanium substrate. The etching target layer 110 may be formed using any one selected from a semiconductor material, a conductive material and an insulating material, or a combination thereof. The etching target layer 110 may be formed as a single layer, or may include multiple layers stacked on the substrate 100.

The photoresist layer 120 may include the resist composition according to embodiments of the inventive concept. The resist composition may include the metal phthalocyanine compound represented by Formula 1 and the solvent. The formation of the photoresist layer 120 may include, for example, applying the resist composition on the etching target layer 110 by using a spin coating method. The formation of the photoresist layer 120 may further include performing heat treatment (for example, soft baking process) on the applied resist composition.

Referring to FIG. 9, an exposing process may be performed on the photoresist layer 120. The exposing process may include irradiating light 140 onto the photoresist layer 120. The light 140 may be extreme ultraviolet or e-beam. For example, the exposing process may include aligning a photomask 130 on the photoresist layer 120 and irradiating light 140 (for example, extreme ultraviolet) onto the photoresist layer 120 through the photomask 130. In another embodiment, the exposing process may include irradiating and scanning light 140 (for example, e-beam) onto the photoresist layer 120 using an e-beam lithography apparatus.

The photoresist layer 120 may include a first part 122 exposed to the light 140 and a second part 124 unexposed to the light 140. In an embodiment, the light may be irradiated onto the first part 122 through the opening part 132 of the photomask 130 and may be blocked by the photomask 130 and not irradiated onto the second part 124.

The resist composition may include radicals produced by the irradiation of the light 140. The aromatic functional group (Formula 2) in the metal phthalocyanine compound represented by Formula 1 may form radicals (for example, carbon radicals) by the irradiation of extreme ultraviolet or e-beam, and accordingly, crosslinking bonding between the metal phthalocyanine compounds represented by Formula 1 may be produced. The first part 122 of the photoresist layer 120 may include a macro molecular structure by the crosslinking bonding of the metal phthalocyanine compounds represented by Formula 1. The second part 124 of the photoresist layer 120 may include a monomolecular structure of the metal phthalocyanine compound represented by Formula 1. Through the exposing process, the first part 122 and the second part 124 of the photoresist layer 120 may have different chemical structures.

Referring to FIG. 10, after the exposing process, the photomask 130 may be removed. A developing process may be conducted on the exposed photoresist layer 120. The developing process may include removing the second part 124 of the photoresist layer 120 using a developing solution. The developing solution may include an organic solvent such as benzotrifluoride (BTF), toluene and isopropanol (ⁱPrOH) or a fluorine-containing solvent. The fluorine-containing solvent may include, for example, 1,3-bis(trifluoromethyl)benzene (BTMB), benzotrifluoride, 1,1,1,2,3,3-hexafluoro-4-(1,1,2,3,3,3-hexafluoropropoxy) pentane (Novec 7600), 3-ethoxy-1,1,1,2,3,4,4,5,5,6,6,6-dodecafluoro-2-(trifluoromethyl)-hexane (Novec 7500) or a combination thereof. By the developing process, the second part 124 of the photoresist layer 120 may be selectively removed. The first part 122 of the photoresist layer 120 may be referred to as a photoresist pattern, and the photoresist pattern 122 may be a negative tone pattern.

Referring to FIG. 11, the etching target layer 110 may be etched using the photoresist layer 122 as an etching mask. The etching of the etching target layer 110 may include a wet or a dry etching process. The etching target layer 110 may be etched to form a lower pattern 110P. The lower pattern 110P may be a semiconductor pattern, a conductive pattern or an insulating pattern in a semiconductor device.

Referring to FIG. 12, after forming the lower pattern 110P, the photoresist pattern 122 may be removed. The photoresist pattern 122 may be removed by, for example, an ashing and/or a strip process.

According to embodiments of the inventive concept, the resist composition may include the metal phthalocyanine compound represented by Formula 1. When extreme ultraviolet or e-beam is irradiated onto the photoresist layer 120 formed using the resist composition, crosslinking bonds may be formed between metal phthalocyanine compounds, and accordingly, the photoresist layer 120 may have excellent sensitivity and resolution with respect to an e-beam or extreme ultraviolet lithography process. In addition, the etching resistance of the photoresist layer 120 may increase due to the metal contained in the metal phthalocyanine compound.

According to the inventive concept, a resist composition may include a metal phthalocyanine compound represented by Formula 1 and a solvent, and aromatic functional groups (for example, fluorinated aromatic functional groups) having different substituents (B₁), represented by Formula 2 may be introduced into the metal phthalocyanine compound. Since the aromatic functional groups (for example, fluorinated aromatic functional groups) having different substituents (B₁) are introduced into the benzene skeleton of the metal phthalocyanine compound, agglomeration between the metal phthalocyanine compounds may be suppressed, and as a result, the solubility of the metal phthalocyanine compound in the solvent may increase, thereby improving the dissolution stability and coatability of the resist composition.

Further, the aromatic functional group (for example, fluorinated aromatic functional group) represented by Formula 2 may form radicals by the irradiation of extreme ultraviolet or e-beam, and accordingly, the metal phthalocyanine compound represented by Formula 1 may be easily crosslinked by the irradiation of extreme ultraviolet or e-beam. Accordingly, a photoresist layer formed by using the photoresist composition may have excellent sensitivity and resolution with respect to an e-beam or extreme ultraviolet lithography process. In addition, due to the metal contained in the metal phthalocyanine compound, etching resistance of the photoresist layer may increase.

Accordingly, a metal phthalocyanine-based non-chemically amplified resist composition, which has high resolution and sensitivity with respect to an e-beam or extreme ultraviolet lithography process, high etching resistance and improved dissolution stability and coatability may be provided, and a method for manufacturing a semiconductor device using the same may be provided.

Although the embodiments of the present invention have been described, it is understood that the present invention should not be limited to the embodiments, but various changes and modifications can be made by one ordinary skilled in the art within the spirit and scope of the present invention as hereinafter claimed.

What is claimed is:

1. A resist composition for photolithography, the composition comprising a metal phthalocyanine compound represented by the following Formula 1: 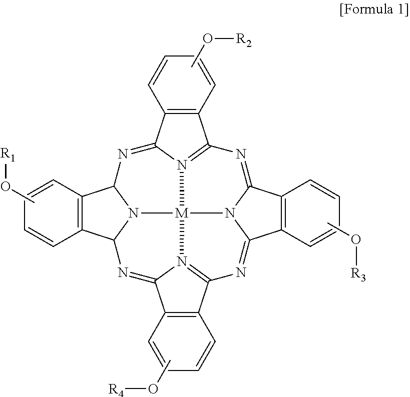
in Formula 1, M is at least one metal selected from tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr) and manganese (Mn), and R₁, R₂, R₃ and R₄ are each independently a functional group represented by the following Formula 2: 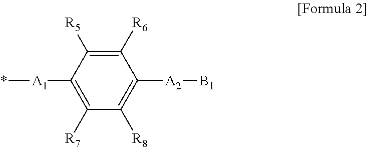
in Formula 2, A₁ and A₂ are each independently a single bond, or a connecting group represented by —CₙH₂ₙ—(“n” is an integer of 1 to 4), —O—, or —CₙH₂ₙ—O—(“n” is an integer of 1 to 4), R₅, R₆, R₇ and R₈ are each independently hydrogen or halogen, B₁ is a vinyl group, a halogenated alkyl group of 1 to 20 carbon atoms, a halogenated alkyl ether halogenated alkyl group of 2 to 20 carbon atoms, a halogenated alkyl ether halogenated alkylene ether halogenated alkyl group of 3 to 20 carbon atoms, or a halogenated aryl group of 6 to 20 carbon atoms, and * is a part bonded to oxygen in Formula 1.

2. The resist composition for photolithography of claim 1, wherein, in Formula 2, R₅, R₆, R₇ and R₈ are each independently fluorine.

3. The resist composition for photolithography of claim 2, wherein, in Formula 2, B₁ is a vinyl group, a fluoroalkyl group of 1 to 20 carbon atoms, a fluoroalkyl ether fluoroalkyl group of 2 to 20 carbon atoms, a fluoroalkyl ether fluoroalkylene ether fluoroalkyl group of 3 to 20 carbon atoms, or a fluoroaryl group of 6 to 20 carbon atoms.

4. The resist composition for photolithography of claim 2, wherein, in Formula 2, B₁ is a substituent represented by the following Formula 3-1, Formula 3-2 or Formula 3-3: 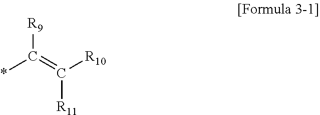
in Formula 3-1, R₉, R₁₀ and R₁₁ are each independently hydrogen, deuterium or an alkyl group of 1 to 3 carbon atoms, and * is a part bonded to A₂ in Formula 2, 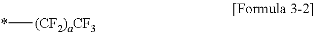
in Formula 3-2, “a” is an integer of 0 to 19, and * is a part bonded to A₂ in Formula 2, 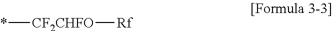
in Formula 3-3, Rf has a structure of —CₓF₂ₓ₊₁ or —CₓF₂ₓ—O—C_{y}F_{2y+1}, “x” and “y” are each an integer of 1 or more, x+y is an integer of 2 to 10, and * is a part bonded to A₂ in Formula 2.

5. The resist composition for photolithography of claim 1, wherein, in Formula 1, R₁, R₂, R₃ and R₄ are each independently a fluorinated aromatic functional group represented by the following Formula 2-1, Formula 2-2 or Formula 2-3: 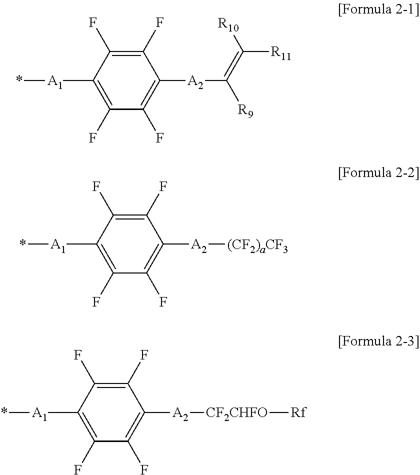
in Formula 2-1, R₉, R₁₀ and R₁₁ are each independently hydrogen, deuterium or an alkyl group of 1 to 3 carbon atoms,
in Formula 2-2, “a” is an integer of 0 to 19,
in Formula 2-3, Rf has a structure of —CₓF₂ₓ₊₁ or —CₓF₂ₓ—O—C_{y}F_{2y+1}, “x” and “y” are each an integer of 1 or more, and x+y is an integer of 2 to 10, and
in Formula 2-1 to Formula 2-3, A₁ and A₂ are each independently a single bond, or a connecting group represented by —CₙH₂ₙ—(“n” is an integer of 1 to 4), —O—, or —CₙH₂ₙ—O—(“n” is an integer of 1 to 4), and * is a part bonded to oxygen in Formula 1.

6. The resist composition for photolithography of claim 5, wherein, in Formula 1, at least two among R₁, R₂, R₃ and R₄ are fluorinated aromatic functional groups having different structures among Formula 2-1 to Formula 2-3 above.

7. The resist composition for photolithography of claim 5, wherein the metal phthalocyanine compound represented by Formula 1 is a zinc phthalocyanine compound represented by the following Formula 1-1: 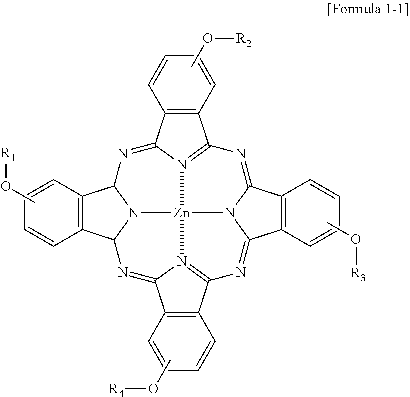
in Formula 1-1, R₁, R₂, R₃ and R₄ are each independently a fluorinated aromatic functional group represented by Formula 2-1, Formula 2-2 or Formula 2-3 above, and at least two among R₁, R₂, R₃ and R₄ are fluorinated aromatic functional groups having different structures among Formula 2-1 to Formula 2-3 above.

8. The resist composition for photolithography of claim 1, further comprising:
a solvent,
wherein the solvent comprises an organic solvent or a fluorine-containing solvent.

9. A method for manufacturing a semiconductor device, the method comprising:
forming an etching target layer on a substrate;
forming a photoresist layer on the etching target layer; and
performing an exposing process on the photoresist layer, wherein
the exposing process is performed using extreme ultraviolet or e-beam,
the photoresist layer comprises a metal phthalocyanine compound in which a fluorinated aromatic functional group is introduced, and
the fluorinated aromatic functional group comprises a substituent selected among a vinyl group, a fluoroalkyl group of 1 to 20 carbon atoms, a fluoroalkyl ether fluoroalkyl group of 2 to 20 carbon atoms, a fluoroalkyl ether fluoroalkylene ether fluoroalkyl group of 3 to 20 carbon atoms, and a fluoroaryl group of 6 to 20 carbon atoms.

10. The method for manufacturing the semiconductor device of claim 9,
wherein the photoresist layer comprises a metal phthalocyanine compound in which fluorinated aromatic functional groups having different structures are introduced, and
the fluorinated aromatic functional groups comprise different substituents selected among a vinyl group, a fluoroalkyl group of 1 to 20 carbon atoms, a fluoroalkyl ether fluoroalkyl group of 2 to 20 carbon atoms, a fluoroalkyl ether fluoroalkylene ether fluoroalkyl group of 3 to 20 carbon atoms, and a fluoroaryl group of 6 to 20 carbon atoms.

11. The method for manufacturing the semiconductor device of claim 9, wherein the metal phthalocyanine compound is represented by the following Formula 1: 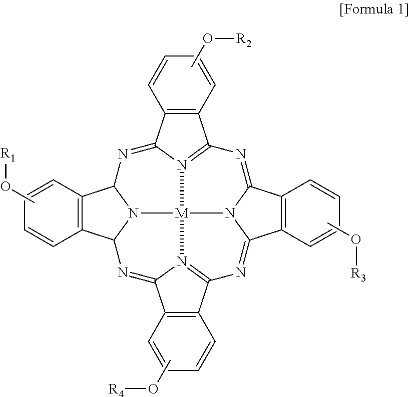
in Formula 1, M is at least one metal selected from tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr) and manganese (Mn), and R₁, R₂, R₃ and R₄ are each independently the fluorinated aromatic functional group represented by the following Formula 2: 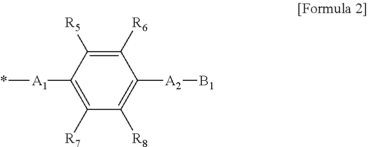
in Formula 2, A₁ and A₂ are each independently a single bond, or a connecting group represented by —CₙH₂ₙ—(“n” is an integer of 1 to 4), —O—, or —CₙH₂ₙ—O—(“n” is an integer of 1 to 4), R₅, R₆, R₇ and R₈ are each independently fluorine, B₁ is the substituent and is a vinyl group, a fluoroalkyl group of 1 to 20 carbon atoms, a fluoroalkyl ether fluoroalkyl group of 2 to 20 carbon atoms, a fluoroalkyl ether fluoroalkylene ether fluoroalkyl group of 3 to 20 carbon atoms, or a fluoroaryl group of 6 to 20 carbon atoms.

12. The method for manufacturing the semiconductor device of claim 11, wherein, in Formula 1, R₁, R₂, R₃ and R₄ are each independently the fluorinated aromatic functional group represented by the following Formula 2-1, Formula 2-2 or Formula 2-3: 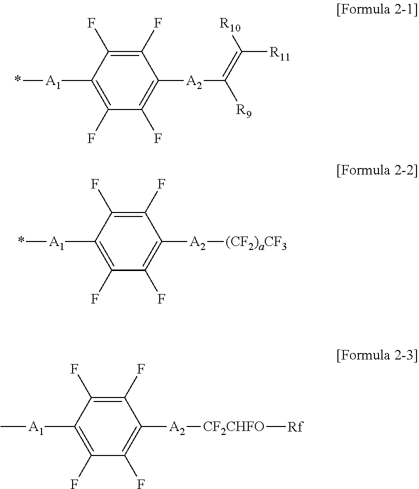
in Formula 2-1, R₉, R₁₀ and R₁₁ are each independently hydrogen, deuterium or an alkyl group of 1 to 3 carbon atoms,
in Formula 2-2, “a” is an integer of 0 to 19,
in Formula 2-3, Rf has a structure of —CₓF₂ₓ₊₁ or —CₓF₂ₓ—O—C_{y}F_{2y+1}, “x” and “y” are each an integer of 1 or more, and x+y is an integer of 2 to 10, and
in Formula 2-1 to Formula 2-3, A₁ and A₂ are each independently a single bond, or a connecting group represented by —CₙH₂ₙ—(“n” is an integer of 1 to 4), —O—, or —CₙH₂ₙ—O—(“n” is an integer of 1 to 4), and * is a part bonded to oxygen in Formula 1.

13. The method for manufacturing the semiconductor device of claim 12, wherein, in Formula 1, at least two among R₁, R₂, R₃ and R₄ are fluorinated aromatic functional groups having different structures among Formula 2-1 to Formula 2-3 above.

14. The method for manufacturing the semiconductor device of claim 9,
wherein the photo resist layer comprises a first part exposed by the exposing process and a second part unexposed by the exposing process, and
the method further comprises performing a developing process for selectively removing the second part of the photoresist layer.

15. A method for manufacturing a semiconductor device, the method comprising:
forming an etching target layer on a substrate; and
forming a photoresist layer on the etching target layer,
wherein the photoresist layer comprises a metal phthalocyanine compound represented by the following Formula 1: 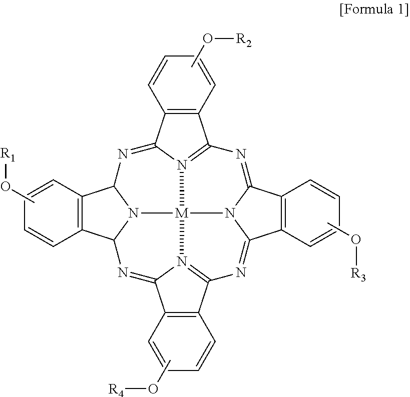
in Formula 1, M is tin (Sn) or zinc (Zn), and R₁, R₂, R₃ and R₄ are each independently a fluorinated aromatic functional group represented by the following Formula 2-1, Formula 2-2 or Formula 2-3: 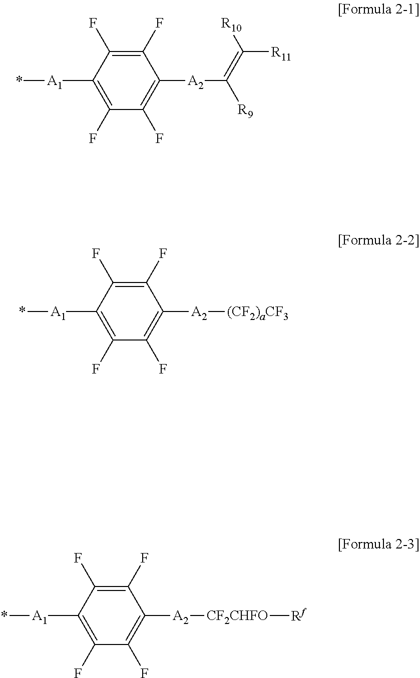
in Formula 2-1, R₉, R₁₀ and R₁₁ are each independently hydrogen, deuterium or an alkyl group of 1 to 3 carbon atoms,
in Formula 2-2, “a” is an integer of 0 to 19,
in Formula 2-3, Rf has a structure of —CₓF₂ₓ₊₁ or —CₓF₂ₓ—O—C_{y}F_{2y+1}, “x” and “y” are each an integer of 1 or more, and x+y is an integer of 2 to 10, and
in Formula 2-1 to Formula 2-3, A₁ and A₂ are each independently a single bond, or a connecting group represented by —CₙH₂ₙ—(“n” is an integer of 1 to 4), —O—, or —CₙH₂ₙ—O—(“n” is an integer of 1 to 4), and * is a part bonded to oxygen in Formula 1.

16. The method for manufacturing the semiconductor device of claim 15, wherein, in Formula 1, at least two among R₁, R₂, R₃ and R₄ are fluorinated aromatic functional groups having different structures among Formula 2-1 to Formula 2-3.

17. The method for manufacturing the semiconductor device of claim 15, further comprising:
performing an exposing process on the photoresist layer,
wherein the exposing process is performed using extreme ultraviolet or e-beam.

18. The method for manufacturing the semiconductor device of claim 17,
wherein the photoresist layer comprises a first part exposed by the exposing process and a second part unexposed by the exposing process, and
the first part of the photoresist layer comprises a crosslinked structure of the metal phthalocyanine compound represented by Formula 1.

19. The method for manufacturing the semiconductor device of claim 18, wherein the second part of the photoresist layer comprises a single molecular structure of the metal phthalocyanine compound represented by Formula 1.

20. The method for manufacturing the semiconductor device of claim 19, further comprising:
performing a developing process for selectively removing the second part of the photoresist layer.
